(19) United States
(12) Patent Application Publication
(10) Pub. No.: US 2024/0404925 A1
(43) Pub. Date: Dec. 5, 2024

(54) MOLDED POWER SEMICONDUCTOR PACKAGE

(71) Applicant: Infineon Technologies AG, Neubiberg (DE)

(72) Inventors: Marco Bäßler, Oeversee (DE); Martin Haller, Altdorf bei Landshut (DE)

(21) Appl. No.: 18/205,129

(22) Filed: Jun. 2, 2023

(51) Int. Cl. H01L 23/495; H01L 21/56; H01L 23/31; H01R 12/58

(52) U.S. Cl. CPC H01L 23/49517; H01L 21/56; H01L 23/3107; H01L 23/49575; H01R 12/585

(57) ABSTRACT

A molded power semiconductor package includes a mold compound having first and second opposing main surfaces and an edge between the first and second main surfaces. Power semiconductor dies are embedded in the mold compound. A metallic frame embedded in the mold compound is electrically connected to the power semiconductor dies. Pins protrude from the first main surface of the mold compound, each pin being secured to a respective contact area of the metallic frame that is exposed by an opening in the mold compound at the first main surface. One or more of the openings extends to the edge of the mold compound to form an open channel from each contact area exposed by the one or more of the openings to the edge of the mold compound. Additional package embodiments and methods of production are also described.

### BACKGROUND

Molded power semiconductor packages include power semiconductor dies embedded in a mold compound and electrically interconnected to form a power electronics circuit. Some electrical contacts for the embedded power semiconductor dies are provided by pins that protrude through openings in the mold compound and that are attached to a metallic structure also embedded in the mold compound. The power electronics circuit formed by the power semiconductor dies embedded in the mold compound is typically tested before the pins are attached to the metallic structure also embedded in the mold compound, which requires contacting of the metallic structure by test pins (probes) through openings in the mold compound. However, a thin layer of mold flash typically covers the regions of the embedded metallic structure to be contacted/probed during testing and interferes with the testing process.

Hence, there is a need for an improved molded power semiconductor package and production process that eliminates the mold flash problem.

### SUMMARY

According to an embodiment of a molded power semiconductor package, the molded power semiconductor package comprises: a mold compound having a first main surface, a second main surface opposite the first main surface, and an edge between the first main surface and the second main surface; a plurality of power semiconductor dies embedded in the mold compound; a metallic frame embedded in the mold compound and electrically connected to the power semiconductor dies; and a plurality of pins protruding from the first main surface of the mold compound, wherein each pin is secured to a respective contact area of the metallic frame that is exposed by an opening in the mold compound at the first main surface, wherein one or more of the openings has a first linear dimension (a) in a vertical direction generally perpendicular to the first main surface, a second linear dimension (l) in a first horizontal direction generally parallel to the first main surface, and a third linear dimension (b) in a second horizontal direction transverse to the first horizontal direction, wherein b>a and l>2a.

According to another embodiment of a molded power semiconductor package, the molded power semiconductor package comprises: a mold compound having a first main surface, a second main surface opposite the first main surface, and an edge between the first main surface and the second main surface; a plurality of power semiconductor dies embedded in the mold compound; a metallic frame embedded in the mold compound and electrically connected to the power semiconductor dies; and a plurality of pins protruding from the first main surface of the mold compound, wherein each pin is secured to a respective contact area of the metallic frame that is exposed by an opening in the mold compound at the first main surface, wherein one or more of the openings extends to the edge of the mold compound to form an open channel from each contact area exposed by the one or more of the openings to the edge of the mold compound.

According to an embodiment of a method of producing a molded power semiconductor package, the method comprises: embedding a plurality of power semiconductor dies and a metallic frame electrically connected to the power semiconductor dies in a mold compound, the mold compound having a first main surface, a second main surface opposite the first main surface, and an edge between the first main surface and the second main surface; during the embedding, forming a plurality of openings in the first main surface of the mold compound and aligned with respective contact areas of the metallic frame, wherein one or more of the openings extends to the edge of the mold compound to form an open channel from each contact area aligned with the one or more of the openings to the edge of the mold compound; after the embedding, performing a de-flashing process to remove mold compound flash from the contact areas of the metallic frame, wherein each open channel provides an ingress or egress path for a chemical de-flashing agent of the de-flashing process; and after the de-flashing process, securing a plurality of pins to the contact areas of the metallic frame.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a top perspective view of an embodiment of a molded power semiconductor package having a metallic frame embedded in a mold compound and pins secured to contact areas of the metallic frame that are exposed by openings in the mold compound.

FIG. 2 illustrates partial cross-sectional views of different configuration examples for the openings in the mold compound, for a first pin type.

FIG. 3 illustrates a partial top perspective view of the molded power semiconductor package in a region of an opening in the mold compound near the edge of the mold compound.

FIG. 4 illustrates the same partial cross-sectional views as FIG. 2, but for a second pin type.

FIG. 5 illustrates a cross-sectional view of an opening in the mold compound near the edge of the mold compound, during a de-flashing process.

FIG. 6 illustrates a cross-sectional view of an opening in the mold compound spaced further inward from the edge of the mold compound than the opening in FIG. 5, during the de-flashing process.

### DETAILED DESCRIPTION

The embodiments described herein provide a molded power semiconductor package having openings in a first main surface of the mold compound that expose contact areas of a metallic frame embedded in the mold compound. The contact areas enable electrical testing and provide for subsequent attachment of pins that form permanent external contacts to the package. The openings are dimensioned to increase the contact area between a chemical de-flashing agent and the contact areas of the metallic frame, enabling the chemical de-flashing agent to reliably remove mold compound flash from the contact areas. For each opening near the side edge of the mold compound, the opening may extend to the edge of the mold compound to form an open channel for carrying the chemical de-flashing agent to or from the edge of the mold compound.

Described next, with reference to the figures, are exemplary embodiments of the molded power semiconductor package and methods of producing such a power semiconductor package. Any of the embodiments described next may be used interchangeably unless otherwise expressly stated.

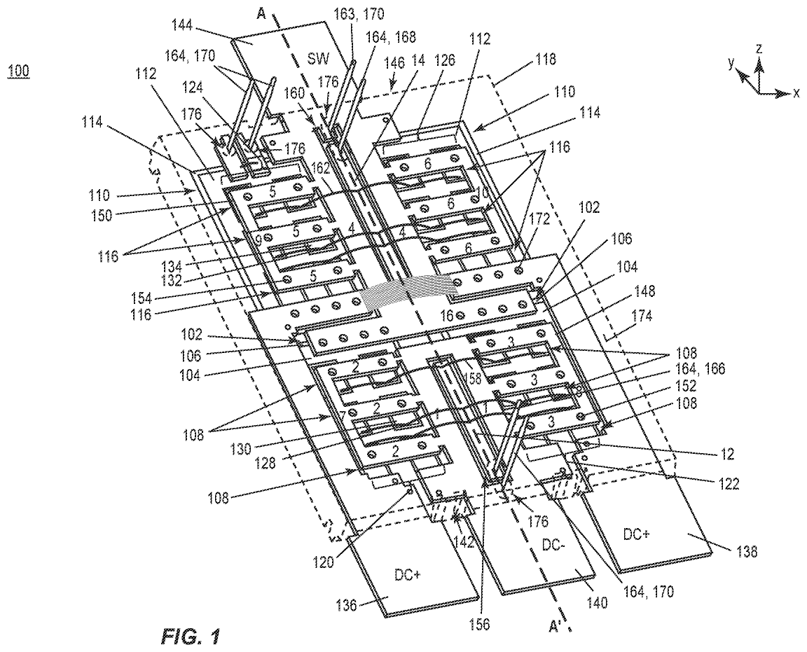

FIG. 1 illustrates a top perspective view of an embodiment of a molded power semiconductor package 100. The molded power semiconductor package 100 may form part of a power electronics circuit for use in various power applications such as in a DC/AC inverter, a DC/DC converter, an AC/DC converter, a DC/AC converter, an AC/AC converter, a multi-phase inverter, an H-bridge, etc.

The molded power semiconductor package 100 includes at least one first power electronics carrier 102 having a metallization layer 104 disposed on an electrically insulating substrate 106. First power semiconductor dies 108 are attached to the metallization layer 104 of the at least one first power electronics carrier 102. The molded power semiconductor package 100 may also include at least one second power electronics carrier 110 having a metallization layer 112 disposed on an electrically insulating substrate 114. Second power semiconductor dies 116 are attached to the metallization layer 112 of the at least one second power electronics carrier 110. A mold compound 118 encases the first power semiconductor dies 108 and the second power semiconductor dies 116, and at least partly encases the at least one first power electronics carrier 102 and the at least one second power electronics carrier 110. In one embodiment, the surface (out of view in FIG. 1) of the first and second power electronics carriers 102, 110 opposite the respective metallization layers 104, 112 is exposed from the mold compound 118 to provided single-sided cooling of the molded power semiconductor package 100.

The outline of the mold compound 118 is shown in FIG. 1 to provide an unobstructed view of the elements embedded in the mold compound 118. The at least one first power electronics carrier 102 and the at least one second power electronics carrier 110 may be positioned aside one another in the x-y plane or vertically stacked one on top of the other in the z direction.

Each first power electronic carrier 102 and each second power electronics carrier 110 may be, e.g., a DCB (direct copper bonded) substrate, an AMB (active metal brazed) substrate, an IMS (insulated metal substrate), etc. The first power semiconductor dies 108 and the second power semiconductor dies 116 may be power Si or SiC power MOSFET (metal-oxide-semiconductor field-effect transistor) dies, HEMT (high-electron mobility transistor) dies, IGBT (insulated-gate bipolar transistor) dies, JFET (junction filed-effect transistor) dies, etc.

As shown in FIG. 1, the first power semiconductor dies 108 and the second power semiconductor dies 116 are vertical power transistor dies. For a vertical power transistor die, the primary current flow path is between the front and back sides of the die. The drain terminal is typically disposed at the backside of the die, with the gate and source terminals (and optionally one or more sense terminals) at the frontside of the die 110. Additional types of semiconductor dies may be included in the molded power semiconductor package 100, such as power diode dies, logic dies, controller dies, gate driver dies, etc.

The first power semiconductor dies 108 may be attached to the metallization layer 104 of a single first power electronics carrier 102, with a first subset 120 and a second subset 122 of the first power semiconductor dies 108 being symmetrically arranged on the single first power electronics carrier 102 about a longitudinal centerline A-A′ of the molded power semiconductor package 100. The second power semiconductor dies 116 similarly may be attached to the metallization layer 112 of a single second power electronics carrier 110, with a first subset 124 and a second subset 126 of the second power semiconductor dies 116 also being symmetrically arranged on the single second power electronics carrier 110 about the longitudinal centerline A-A′ of the molded power semiconductor package 100.

The first and second subsets 120, 122 of the first power semiconductor dies 108 instead may be attached to separate first power electronics carriers 102 as shown in FIG. 1, with the separate first power electronics carriers 108 being arranged symmetrically with respect to one another about the longitudinal centerline A-A′ of the molded power semiconductor package 100. The first and second subsets 124, 126 of the second power semiconductor dies 116 similarly may be attached to separate second power electronics carriers 110, with the separate second power electronics carriers 110 also being arranged symmetrically with respect to one another about the longitudinal centerline A-A′ of the molded power semiconductor package 100.

In the example illustrated in FIG. 1, the first power semiconductor dies 108 are arranged symmetrically about the package longitudinal centerline A-A′ in three rows (x-direction) with four (two on each side of the longitudinal centerline A-A′) first power semiconductor dies 108 in each row. The second power semiconductor dies 116 are also arranged symmetrically about the package longitudinal centerline A-A′ in three rows (x-direction) with four (two on each side of the longitudinal centerline A-A′) second power semiconductor dies 116 in each row. More generally, the molded power semiconductor package 100 may include at least two first power semiconductor dies 108 and at least two second power semiconductor dies 116, with an equal number of first power semiconductor dies 108 and an equal number of second power semiconductor dies 116 being arranged on both sides of the longitudinal centerline A-A′ of the package 100. This ensures a symmetric layout of both the power semiconductor dies 108, 116 and the power electronics carriers 102, 110 within the molded body 118 of the package 100.

The first power semiconductor dies 108 and the second power semiconductor dies 116 may be electrically interconnected to form a power electronics circuit such as a half bridge, e.g., with the first power semiconductor dies 108 forming a low-side switch of the half bridge and the second power semiconductor dies 116 forming a high-side switch of the half bridge. For the vertical die arrangement shown in FIG. 1, the drain terminal (out of view in FIG. 1) of each first power semiconductor die 108 is connected to the metallization layer 104 of the at least one first power electronics carrier 102 with gate and source terminals 128, 130 (and optionally one or more sense terminals) at the opposite frontside of the first dies 108. The drain terminal (out of view in FIG. 1) of each second power semiconductor die 116 is similarly connected to the metallization layer 112 of the at least one second power electronics carrier 110 with gate and source terminals 132, 134 (and optionally one or more sense terminals) at the opposite frontside of the second dies 116.

At least one lead 136, 138, 140 protrudes from a first side face 142 of the mold compound 118 and at least one lead 144 protrudes from a second side face 146 of the mold compound 118 opposite the first side face 142. The longitudinal centerline A-A′ of the molded power semiconductor package 100 extends between the first and second side faces 142, 146 of the mold compound 118.

In FIG. 1, two high-side power leads 136, 138 protrude from the first side face 142 of the mold compound 118 to provide a DC+ power connection to the second (high-side) power semiconductor dies 116. The first high-side power lead 136 provides the DC+ power connection to the first subset 124 of the second power semiconductor dies 116 and the second high-side power lead 138 provides the DC+ power connection to the second subset 126 of the second power semiconductor dies 116. A low high-side power lead 140 also protrudes from the first side face 142 of the mold compound 118 and provides a DC− power connection to the first (low-side) power semiconductor dies 108. The low-side power lead 140 is interposed between the first and second high-side power leads 136, 138.

A switch node lead 144 protrudes from the second side face 146 of the mold compound 118 and is electrically connected to the switch node ‘SW’ between the high-side power semiconductor dies 116 and the low-side power semiconductor dies 108 of the half bridge. In this case, the switch node lead 144 is the output lead for the molded power semiconductor package 100.

The internal electrical connections between the package leads 136, 138, 140, 144 and the power semiconductor dies 108, 116 encased in the mold compound 118 may be provided by a metallic frame embedded in the mold compound 118. In FIG. 1, the metallic frame includes a first structured metal frame 148 disposed above the at least one first power electronics carrier 102 and a second structured metal frame 150 disposed above the at least one second power electronics carrier 110. The first structured metal frame 148 and the second structured metal frame 150 may be part of a lead frame with the features of the structured metal frames 148, 150 being formed by stamping, punching, etching, etc.

In FIG. 1, both the first structured metal frame 148 and the second structured metal frame 150 are symmetric about the longitudinal centerline A-A′ of the molded power semiconductor package 100. The terms ‘symmetric’ and ‘symmetrical’ as used herein include unavoidable asymmetry which may arise due to manufacturing tolerances. However, asymmetry may be intentionally introduced into the metallic frame formed by the first structured metal frame 148 and the second structured metal frame 150. For example, all semiconductor dies 108, 116 may face the same direction which can introduce a minor asymmetry in the metallic frame relative to the center line A-A′ of the molded power semiconductor package 100.

In either case, the first structured metal frame 148 is electrically connected to the source terminal 130 of each first (low-side) power semiconductor die 108, e.g., by bumps or stamped features 152 at the backside of the first structured metal frame 148, or by solder, electrically conductive adhesive, etc. The second structured metal frame 150 is electrically connected to the source terminal 134 of each second (high-side) power semiconductor die 116, e.g., by bumps or stamped features 154 at the backside of the second structured metal frame 150, or by solder, electrically conductive adhesive, etc.

A first subset 120 and a second subset 122 of the first power semiconductor dies 108 may be arranged on opposite sides of the longitudinal centerline A-A′ of the molded power semiconductor package 100, as previously described herein. A first subset 124 and a second subset 126 of the second power semiconductor dies 116 similarly may be arranged on opposite sides of the longitudinal centerline A-A′.

As shown in FIG. 1, the first structured metal frame 148 may include a first central part ‘1’ that extends along the longitudinal centerline A-A′. First branches ‘2’ each joined at a proximal end to the first central part ‘1’ extend in parallel over the first subset 120 of first power semiconductor dies 108 in a first lateral direction (−x direction in FIG. 1) that is transverse to the longitudinal centerline A-A′. Second branches ‘3’ each joined at a proximal end to the first central part ‘1’ extend in parallel over the second subset 122 of first power semiconductor dies 116 in a second lateral direction (x direction in FIG. 1) opposite the first lateral direction.

Further as shown in FIG. 1, the second structured metal frame 150 includes a second central part ‘4’ that extends along the longitudinal centerline A-A′. Third branches ‘5’ each joined at a proximal end to the second central part ‘4’ extend in parallel over the first subset 124 of second power semiconductor dies 116 in the first lateral direction. Fourth branches ‘6’ each joined at a proximal end to the second central part ‘4’ extend in parallel over the second subset 126 of second power semiconductor dies 116 in the second lateral direction.

The first branches ‘2’ of the metallic frame are vertically connected to the source terminal 130 of each power semiconductor die 108 included in the first subset 120 of first power semiconductor dies 108. The second branches ‘3’ of the metallic frame are vertically connected to the source terminal 130 of each power semiconductor die 108 included in the second subset 122 of first power semiconductor dies 108. The third branches ‘5’ of the metallic frame are vertically connected to the source terminal 134 of each power semiconductor die 116 included in the first subset 124 of second power semiconductor dies 116. The fourth branches ‘6’ of the metallic frame are vertically connected to the source terminal 134 of each power semiconductor die 116 included in the second subset 126 of second power semiconductor dies 116.

The first structured metal frame 148 of the metallic frame may include a first additional ‘7’ branch that connects the first branches ‘2’ at a distal end of the first branches ‘2’, and a second additional branch ‘8′ that connects the second branches ‘3’ at a distal end of the second branches ‘3’. The second structured metal frame 150 of the metallic frame may include a third additional branch ‘9′ that connects the third branches ‘5’ at a distal end of the third branches ‘5’, and a fourth additional branch ‘10′ that connects the fourth branches ‘6’ at a distal end of the fourth branches 6′.

The first structured metal frame 148 of the metallic frame may include a first gate metallization ‘12′ disposed in an opening 156 formed in the first central part ‘1’ of the first structured metal frame 148 and that is electrically insulated from the first central part ‘1’, the first branches ‘2’, and the second branches ‘3’. The first gate metallization ‘12′ is electrically connected to the gate terminal 128 of each first power semiconductor die 108, e.g., by bond wires 158. The second structured metal frame 150 of the metallic frame may include a second gate metallization ‘14′ disposed in an opening 160 formed in the second central part ‘4’ of the second structured metal frame 150 and that is electrically insulated from the second central part ‘4’, the third branches ‘5’, and the fourth branches ‘6’. The second gate metallization ‘14′ is electrically connected to the gate terminal 132 of each second power semiconductor die 118, e.g., by bond wires 162.

The first and second gate metallizations ‘12’, ‘14’ may be part of a lead frame, as explained above. The first and second gate metallizations ‘12’, ‘14’ instead may be part of respective first and second PCBs disposed in the corresponding openings 156, 160 formed in the first central part ‘1’ and the second central part ‘4’ of the metallic frame. In yet another example, the first and second gate metallizations ‘12’, ‘14’ may be part of respective first and second additional power electronics carriers disposed in the corresponding openings 156, 160 formed in the first central part ‘1’ and the second central part ‘4’ of the metallic frame.

The second structured metal frame 150 of the metallic frame may include an additional branch ‘16′ at the end of the second central part ‘4’ of the second structured metal frame 150 and that faces the first structured metal frame 148. The additional branch ‘16′ extends in parallel with both the third branches ‘5’ and the fourth branches ‘6’ of the second structured metal frame 150.

The additional branch ‘16′ is vertically connected to the metallization layer 104 of the at least one first power electronics carrier 102, e.g., by bumps or stamped features 172 at the backside of additional branch ‘16′, or by solder, electrically conductive adhesive, etc.

The source connections to the first power semiconductor dies 108 instead may be formed by first bond wires (not shown) which connect the first central part ‘1’ of the first structured metal frame 148 to the source terminal 130 of each first power semiconductor die 108 and the source connections to the second power semiconductor dies 116 similarly may be formed by second bond wires (not shown) which connect the second central part ‘4’ of the second structured metal frame 150 to the source terminal 134 of each second power semiconductor die 116.

Accordingly, branches ‘2’, ‘3’, ‘7’ and ‘8′ of the first structured metal frame 148 and branches ‘5’, ‘6’, ‘9’ and ‘10′ of the second structured metal frame 150 may be omitted from the metallic frame and replaced by bond wires. The additional branch ‘16′ of the second structured metal frame 150 may be electrically connected to the metallization layer 104 of the at least one first power electronics carrier 102 by third bond wires (not shown) to complete the switch node connection ‘SW’.

In FIG. 1, the metallization layer 104 of the least one first power electronics carrier 102 is electrically connected to the drain terminal (out of view) of each first power semiconductor die 108. The metallization layer 112 of the least one second power electronics carrier 110 is electrically connected to the drain terminal (out of view) of each second power semiconductor die 116. The first structured metal frame 148 is electrically connected to the source terminal 130 of each first power semiconductor die 108. The second structured metal frame 150 is electrically connected to the source terminal 134 of each second power semiconductor die 116. The additional branch ‘16′ of the second structured metal frame 150 forms the switch node connection ‘SW’ between the drain terminal of each first power semiconductor die 108 and the source terminal 134 of each second power semiconductor die 116.

In FIG. 1, the first high-side power lead 136 and the second high-side power lead 138 are both electrically connected to the metallization layer 112 of the at least one second power electronics carrier 110. The first high-side power lead 136 flanks one side of the first structured metal frame 148 and the second high-side power lead 138 flanks the opposite side of the first structured metal frame 148 as the first high-side power lead 136.

An end of the first structured metal frame 148 may protrude from the first side face 142 of the mold compound 118 to form the low high-side power lead 140 of the molded power semiconductor package 100. An end of the second structured metal frame 150 may protrude from the second side face 146 of the mold compound 118 to form the switch node lead 144 of the molded power semiconductor package 100.

Pins 164 protrude from a first (e.g., front) main surface 174 of the mold compound 118. The opposite (e.g., bottom) main face of the mold compound 118 is out of view in FIG. 1.

The pins 164 may be signal pins such as gate pins and/or sense pins such as current, voltage and/or temperature sense pins. For example, a first pin 166 may be attached to the first gate metallization ‘12′ and protrude through the first main surface 174 of the mold compound 118.

A second pin 168 may be attached to the second gate metallization ‘14′ and protrude through the first main surface 174 of the mold compound 118. Additional press-fit pins 170 may be attached to the first structured metal frame 148 and/or the second structured metal frame 150 and protrude through the first main surface 174 of the mold compound 118, e.g., for external current sensing, voltage sensing, temperature sensing, etc.

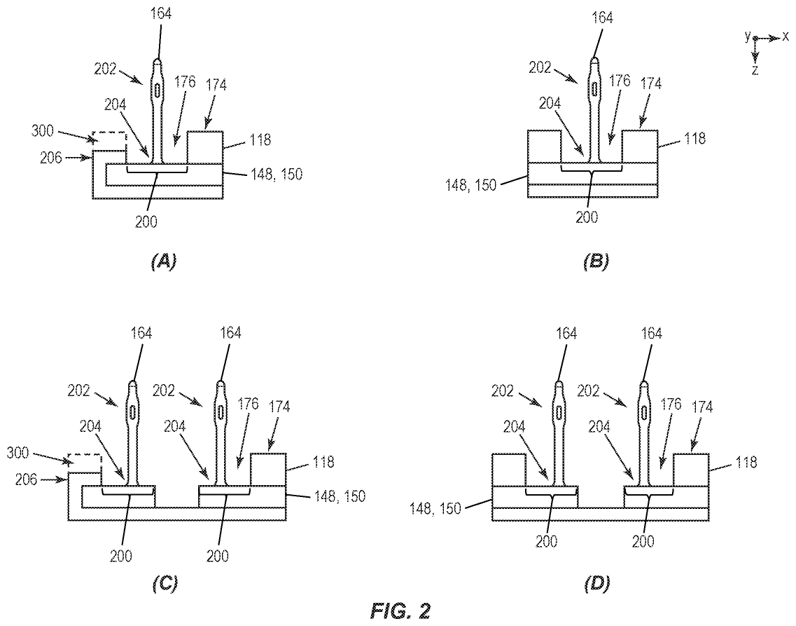

As shown in more detail in FIG. 2, each pin 164 is secured to a respective contact area 200 of the metallic frame 148/150 that is exposed by an opening 176 in the mold compound 118 at the first main surface 174. The pins 164 may be press-fit pins, for example. A press-fit pin has a pin geometry that enables plastic and/or elastic deformation in an end region of the pin when the pin is inserted into an opening of a circuit board such as a PCB (printed circuit board) or other type of component, providing effective contact points within the contact zone. The contact radius increases due to the contact pressure since the macroscopic contact force concentrates on a microscopic contact area. Accordingly, the pin face and the metallized face of the opening of the circuit board or other component merge, i.e., are cold welded. In FIG. 2, the distal end 202 of each pin 164 has a press-fit geometry for insertion into an opening of a circuit board (not shown) and the proximal end 204 is attached to the respective contact area 200 of the metallic frame 148/150, e.g., by a welded joint, brazed joint, solder, etc.

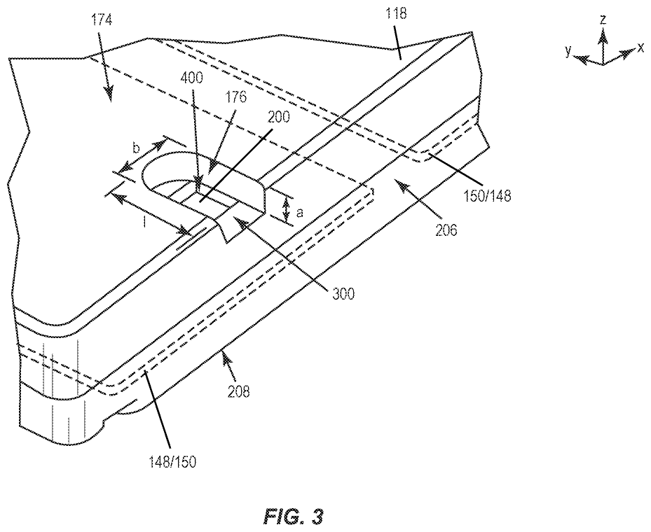

FIG. 3 illustrates a side perspective view of the molded power semiconductor package 100 in a region of one of the openings 176 in the mold compound 118, before a pin 164 is secured to the contact 200 area of the metallic frame 148/150 exposed by the illustrated opening 176.

As shown in FIG. 1, FIG. 3, and examples (A) and (C) in FIG. 2, one or more of the openings 176 may be formed near an edge 206 of the mold compound 118 that extends between the first main surface 174 and the second main surface (out of view) of the mold compound 118. For each opening 176 formed in the first main surface 174 near the edge 206 of the mold compound 118, the opening 176 extends to the edge 206 to form an open channel 300 from the contact area 200 of the metallic frame 148/150 exposed by the opening 176 to the edge 206 of the mold compound 118.

The open channel 300 may be realized by forming a notch in the edge 206 of the mold compound 118 that extends to the corresponding opening 176, as indicated by the dashed rectilinear shape shown in examples (A) and (C) of FIG. 2. For example, during the embedding (molding) process, the mold tool used to overmold the package 100 may have a protrusion or die to create a notch in the edge 206 of the mold compound 118 that forms each open channel 300.

The contact areas 200 of the metallic frame 148/150 that are exposed by the openings in the mold compound 118 may be used for electrical testing and provide for subsequent attachment of the pins 164 which form permanent external contacts to the molded power semiconductor package 100. The openings 176 in the mold compound 118 are dimensioned to increase the contact area between a chemical de-flashing agent and the contact areas 200 of the metallic frame 148/150. The increased contact area enables the chemical de-flashing agent to reliably remove mold compound flash from the contact areas 200, thereby ensuring open contact points for electrical testing prior to pin placement and improving pin placement reliability after electrical testing.

For example, the mold compound opening 176 illustrated in FIG. 3 has a first linear dimension (a) in a vertical direction (z-direction in FIG. 3) generally perpendicular to the first main surface 174 of the mold compound 118, a second linear dimension (l) in a first horizontal direction (y-direction in FIG. 3) generally parallel to the first main surface 174, and a third linear dimension (b) in a second horizontal direction (x-direction in FIG. 3) transverse to the first horizontal direction.

The first linear dimension ‘a’ may be thought of as the height of the mold compound opening 176, the second linear dimension ‘T’ as the length, and the third linear dimension ‘b’ as the width. In one embodiment, the third linear dimension is greater than the first linear dimension (i.e., b>a) and the second linear dimension is greater than twice the first linear dimension (i.e., l>2a). Separately or in combination, for each opening 176 near the edge 206 of the mold compound 119, the opening 176 may extend to the edge 206 of the mold compound 118 to form an open channel 300 for carrying the chemical de-flashing agent to or from the edge 206 of the mold compound 118. The open channel 300 enables the chemical de-flashing agent to flow more easily over the contact areas 200 of the metallic frame 148/150, as explained above. The openings 176 in the first main surface 174 of the mold compound 118 spaced further inward from the edge 206 of the mold compound 118 may not have the open channel 300, depending on the distance to the edge 118 and other factors such as module layout, pin placement, etc. Examples (B) and (D) of FIG. 2 show such an inwardly spaced opening 176 without an open channel 300 to the edge 206 of the mold compound 118, where the edge 206 of the mold compound 118 is out of view.

As shown in FIG. 1 and examples (C) and (D) of FIG. 2, two or more pins 164 may protrude from the first main surface 174 of the mold compound 118 through the same opening 176. Each opening 176 through which two or more pins 164 protrude from the first main surface 174 of the mold compound 118 may have an elliptical shape as shown in FIG. 1, FIG. 3, and examples (B) and (D) of FIG. 2, e.g., to ensure adequate pin clearance. The openings 176 may have other shapes such as square, rectangular, circular, hexagonal, etc. In the case of two or more pins 164 protruding from the first main surface 174 of the mold compound 118 through the same opening 176, the pins 164 may be secured to different contact areas 200 of the metallic frame 148/150 which may be physically separate from one another, e.g., as shown in FIG. 1 and examples (C) and (D) of FIG. 2 and therefore carry different signals.

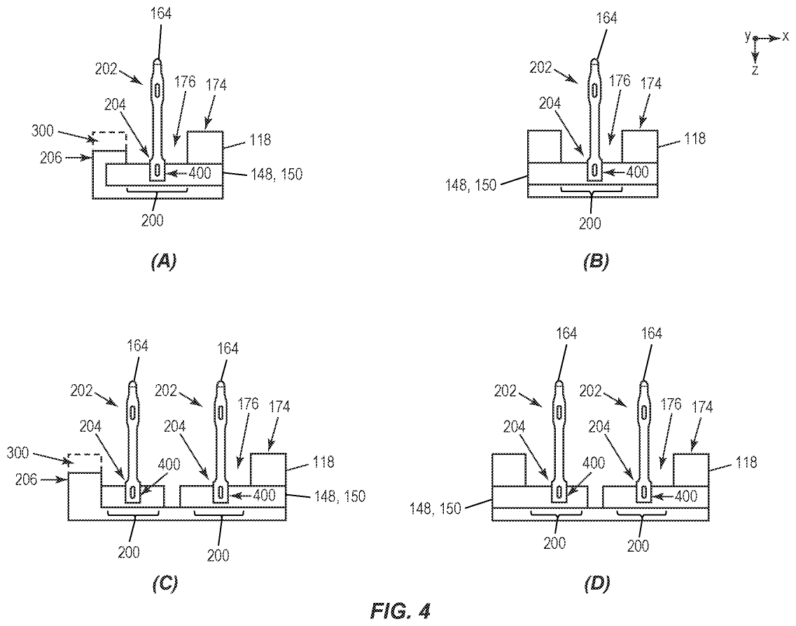

FIG. 4 shows the same mold compound opening configuration examples as FIG. 2, but with a different pin type. In FIG. 4, the proximal end 204 of each pin 164 has a press-fit geometry for insertion into an opening or cavity 400 in the respective contact area 200 of the metallic frame 148/150. The distal end 202 of each pin 164 also may have a press-fit geometry for insertion into an opening of a circuit board (not shown).

Prior to securing the pins 164 to the respective contact area 200 of the metallic frame 148/150, the molded power semiconductor package 100 may be subjected to a de-flashing process to remove mold compound flash from the contact areas 200 of the metallic frame 148/150. Small amounts of resin typically leak out between two halves of a mold during the embedding (molding) process, producing flash that can partly or completely cover a contact area 200 of the metallic frame 148/150.

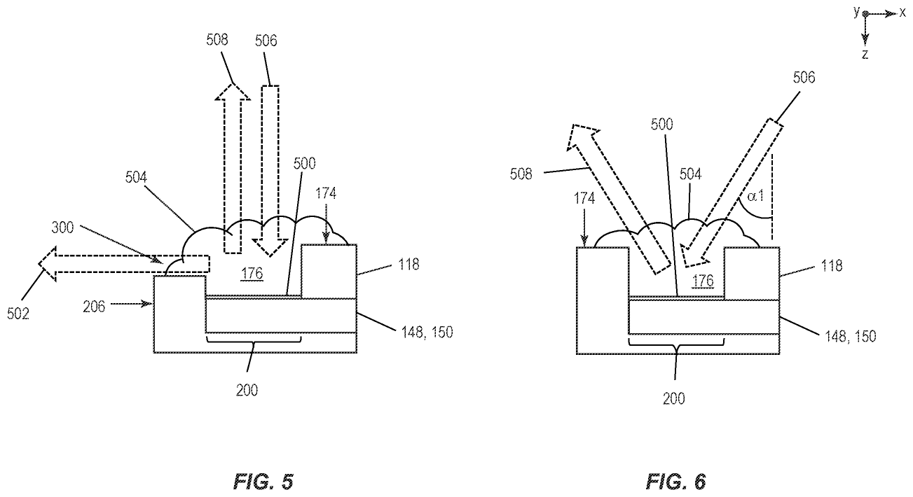

FIG. 5 illustrates an opening 176 in the first main surface 174 of the mold compound 118 near the edge 206 of the mold compound 118, during the de-flashing process. This opening 176 has an open channel 300 that extends from the corresponding contact area 200 of the metallic frame 148/150 to the edge 206 of the mold compound 118, as previously explained herein. In FIG. 5, the power semiconductor dies 108, 116 and the metallic frame 148/150 are already embedded in the mold compound 118. A thin layer of mold compound flash 500 partly or completely covers the contact area 200 of the metallic frame 148/150 that is vertically aligned with the opening 176 formed in the first main surface 174 of the mold compound 118.

After the embedding (molding), the de-flashing process is performed to remove the mold compound flash 500 from each contact area 200 of the metallic frame 148/150. Each open channel 300 that extends from a contact area 200 of the metallic frame 148/150 to the edge 206 of the mold compound 118 provides an ingress or egress path 502 for a chemical de-flashing agent 504 used during the de-flashing process. The chemical de-flashing agent 504 may be, e.g., n-methyl-2-pyrrolidine, dimethyl furane, etc. and may include additives to prevent debris from re-depositing on the contact areas 200 of the metallic frame 148/150 and/or surface active agents to accelerate penetration and promote rapid removal of the mold compound flash 500.

A debris removal stage of the de-flashing process includes directing a pressurized fluid 506 such as compressed air, high pressure water, abrasives, etc. at the openings 176 in the first main surface 174 of the mold compound 118 to remove mold compound flash 508 loosened by the chemical de-flashing agent 504. After the de-flashing process, the pins 164 are secured to the de-flashed contact areas 200 of the metallic frame 148/150, e.g., by press-fitting, brazing, soldering, welding, etc. Electrical testing may be done before or after the pin securing process but after the de-flashing process, to ensure good electrical contact with the contact areas 200 of the metallic frame 148/150.

FIG. 6 illustrates an opening 176 in the first main surface 174 of the mold compound 118 that is spaced further inward from the edge 206 of the mold compound 118 than the opening in FIG. 5, such that the opening 176 in FIG. 6 does not have the open channel 300 to the edge 206 of the mold compound 118. To enhance debris removal in this case, the pressurized fluid 506 may be directed at an angle α1 with respect to the first main surface 174 of the mold compound 118.

Although the present disclosure is not so limited, the following numbered examples demonstrate one or more aspects of the disclosure.

Example 1. A molded power semiconductor package, comprising: a mold compound having a first main surface, a second main surface opposite the first main surface, and an edge between the first main surface and the second main surface; a plurality of power semiconductor dies embedded in the mold compound; a metallic frame embedded in the mold compound and electrically connected to the power semiconductor dies; and a plurality of pins protruding from the first main surface of the mold compound, wherein each pin is secured to a respective contact area of the metallic frame that is exposed by an opening in the mold compound at the first main surface, wherein one or more of the openings has a first linear dimension (a) in a vertical direction generally perpendicular to the first main surface, a second linear dimension (l) in a first horizontal direction generally parallel to the first main surface, and a third linear dimension (b) in a second horizontal direction transverse to the first horizontal direction, wherein b>a and l>2a.

Example 2. The molded power semiconductor package of example 1, wherein each pin is a press-fit pin.

Example 3. The molded power semiconductor package of example 1 or 2, wherein a proximal end of each pin is inserted into an opening in the respective contact area of the metallic frame.

Example 4. The molded power semiconductor package of any of examples 1 through 3, wherein two or more of the pins protrude from the first main surface of the mold compound through the same opening.

Example 5. The molded power semiconductor package of example 4, wherein the opening through which the two or more of the pins protrude from the first main surface of the mold compound has an elliptical shape.

Example 6. The molded power semiconductor package of any of examples 1 through 5, wherein the power semiconductor dies are electrically interconnected, including by the metallic frame, to form a power electronics circuit.

Example 7. The molded power semiconductor package of example 6, wherein the power electronics circuit is a half bridge.

Example 8. The molded power semiconductor package of any of examples 1 through 7, wherein one or more of the openings extends to the edge of the mold compound to form an open channel from the respective contact area to the edge of the mold compound.

Example 9. A molded power semiconductor package, comprising: a mold compound having a first main surface, a second main surface opposite the first main surface, and an edge between the first main surface and the second main surface; a plurality of power semiconductor dies embedded in the mold compound; a metallic frame embedded in the mold compound and electrically connected to the power semiconductor dies; and a plurality of pins protruding from the first main surface of the mold compound, wherein each pin is secured to a respective contact area of the metallic frame that is exposed by an opening in the mold compound at the first main surface, wherein one or more of the openings extends to the edge of the mold compound to form an open channel from each contact area exposed by the one or more of the openings to the edge of the mold compound.

Example 10. The molded power semiconductor package of example 9, wherein each pin is a press-fit pin.

Example 11. The molded power semiconductor package of example 9 or 10, wherein a proximal end of each pin is inserted into an opening in the respective contact area of the metallic frame.

Example 12. The molded power semiconductor package of any of examples 9 through 11, wherein two or more of the pins protrude from the first main surface of the mold compound through the same opening.

Example 13. The molded power semiconductor package of example 12, wherein the opening through which the two or more of the pins protrude from the first main surface of the mold compound has an elliptical shape.

Example 14. The molded power semiconductor package of any of examples 9 through 13, wherein the power semiconductor dies are electrically interconnected, including by the metallic frame, to form a power electronics circuit.

Example 15. The molded power semiconductor package of example 14, wherein the power electronics circuit is a half bridge.

Example 16. The molded power semiconductor package of any of examples 9 through 15, wherein one or more of the openings has a first linear dimension (a) in a vertical direction generally perpendicular to the first main surface, a second linear dimension (l) in a first horizontal direction generally parallel to the first main surface, and a third linear dimension (b) in a second horizontal direction transverse to the first horizontal direction, and wherein b>a and l>2a.

Example 17. A method of producing a molded power semiconductor package, the method comprising: embedding a plurality of power semiconductor dies and a metallic frame electrically connected to the power semiconductor dies in a mold compound, the mold compound having a first main surface, a second main surface opposite the first main surface, and an edge between the first main surface and the second main surface; during the embedding, forming a plurality of openings in the first main surface of the mold compound and aligned with respective contact areas of the metallic frame, wherein one or more of the openings extends to the edge of the mold compound to form an open channel from each contact area aligned with the one or more of the openings to the edge of the mold compound; after the embedding, performing a de-flashing process to remove mold compound flash from the contact areas of the metallic frame, wherein each open channel provides an ingress or egress path for a chemical de-flashing agent of the de-flashing process; and after the de-flashing process, securing a plurality of pins to the contact areas of the metallic frame.

Example 18. The method of example 17, further comprising: directing a pressurized fluid at the openings in the first main surface of the mold compound to remove mold compound flash loosened by the chemical de-flashing agent from the contact areas of the metallic frame, wherein the pressurized fluid is directed at an angle with respect to the first main surface of the mold compound.

Example 19. The method of example 17 or 18, wherein the pins are secured to the contact areas of the metallic frame by press-fitting a proximal end of each pin into an opening in the respective contact area of the metallic frame.

Example 20. The method of any of examples 17 through 19, wherein one or more of the openings has a first linear dimension (a) in a vertical direction generally perpendicular to the first main surface, a second linear dimension (l) in a first horizontal direction generally parallel to the first main surface, and a third linear dimension (b) in a second horizontal direction transverse to the first horizontal direction, and wherein b>a and l>2a.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A molded power semiconductor package, comprising:
a mold compound having a first main surface, a second main surface opposite the first main surface, and an edge between the first main surface and the second main surface;
a plurality of power semiconductor dies embedded in the mold compound;
a metallic frame embedded in the mold compound and electrically connected to the power semiconductor dies; and
a plurality of pins protruding from the first main surface of the mold compound,
wherein each pin is secured to a respective contact area of the metallic frame that is exposed by an opening in the mold compound at the first main surface,
wherein one or more of the openings has a first linear dimension (a) in a vertical direction generally perpendicular to the first main surface, a second linear dimension (l) in a first horizontal direction generally parallel to the first main surface, and a third linear dimension (b) in a second horizontal direction transverse to the first horizontal direction,
wherein b>a and l>2a.

2. The molded power semiconductor package of claim 1, wherein each pin is a press-fit pin.

3. The molded power semiconductor package of claim 1, wherein a proximal end of each pin is inserted into an opening in the respective contact area of the metallic frame.

4. The molded power semiconductor package of claim 1, wherein two or more of the pins protrude from the first main surface of the mold compound through the same opening.

5. The molded power semiconductor package of claim 4, wherein the opening through which the two or more of the pins protrude from the first main surface of the mold compound has an elliptical shape.

6. The molded power semiconductor package of claim 1, wherein the power semiconductor dies are electrically interconnected, including by the metallic frame, to form a power electronics circuit.

7. The molded power semiconductor package of claim 6, wherein the power electronics circuit is a half bridge.

8. The molded power semiconductor package of claim 1, wherein one or more of the openings extends to the edge of the mold compound to form an open channel from the respective contact area to the edge of the mold compound.

9. A molded power semiconductor package, comprising:
a mold compound having a first main surface, a second main surface opposite the first main surface, and an edge between the first main surface and the second main surface;
a plurality of power semiconductor dies embedded in the mold compound;
a metallic frame embedded in the mold compound and electrically connected to the power semiconductor dies; and
a plurality of pins protruding from the first main surface of the mold compound,
wherein each pin is secured to a respective contact area of the metallic frame that is exposed by an opening in the mold compound at the first main surface,
wherein one or more of the openings extends to the edge of the mold compound to form an open channel from each contact area exposed by the one or more of the openings to the edge of the mold compound.

10. The molded power semiconductor package of claim 9, wherein each pin is a press-fit pin.

11. The molded power semiconductor package of claim 9, wherein a proximal end of each pin is inserted into an opening in the respective contact area of the metallic frame.

12. The molded power semiconductor package of claim 9, wherein two or more of the pins protrude from the first main surface of the mold compound through the same opening.

13. The molded power semiconductor package of claim 12, wherein the opening through which the two or more of the pins protrude from the first main surface of the mold compound has an elliptical shape.

14. The molded power semiconductor package of claim 9, wherein the power semiconductor dies are electrically interconnected, including by the metallic frame, to form a power electronics circuit.

15. The molded power semiconductor package of claim 14, wherein the power electronics circuit is a half bridge.

16. The molded power semiconductor package of claim 9, wherein one or more of the openings has a first linear dimension (a) in a vertical direction generally perpendicular to the first main surface, a second linear dimension (l) in a first horizontal direction generally parallel to the first main surface, and a third linear dimension (b) in a second horizontal direction transverse to the first horizontal direction, and wherein b>a and l>2a.

17. A method of producing a molded power semiconductor package, the method comprising:
embedding a plurality of power semiconductor dies and a metallic frame electrically connected to the power semiconductor dies in a mold compound, the mold compound having a first main surface, a second main surface opposite the first main surface, and an edge between the first main surface and the second main surface;
during the embedding, forming a plurality of openings in the first main surface of the mold compound and aligned with respective contact areas of the metallic frame, wherein one or more of the openings extends to the edge of the mold compound to form an open channel from each contact area aligned with the one or more of the openings to the edge of the mold compound;
after the embedding, performing a de-flashing process to remove mold compound flash from the contact areas of the metallic frame, wherein each open channel provides an ingress or egress path for a chemical de-flashing agent of the de-flashing process; and
after the de-flashing process, securing a plurality of pins to the contact areas of the metallic frame.

18. The method of claim 17, further comprising:
directing a pressurized fluid at the openings in the first main surface of the mold compound to remove mold compound flash loosened by the chemical de-flashing agent from the contact areas of the metallic frame,
wherein the pressurized fluid is directed at an angle with respect to the first main surface of the mold compound.

19. The method of claim 17, wherein the pins are secured to the contact areas of the metallic frame by press-fitting a proximal end of each pin into an opening in the respective contact area of the metallic frame.

20. The method of claim 17, wherein one or more of the openings has a first linear dimension (a) in a vertical direction generally perpendicular to the first main surface, a second linear dimension (l) in a first horizontal direction generally parallel to the first main surface, and a third linear dimension (b) in a second horizontal direction transverse to the first horizontal direction, and wherein b>a and l>2a.
